(19) United States
(12) Patent Application Publication
(10) Pub. No.: US 2026/0149355 A1
(43) Pub. Date: May 28, 2026

(54) Method for Operating a Frequency Converter and Frequency Converter

(71) Applicant: Lenze Swiss AG, Romanshorn (CH)

(72) Inventor: Andreas BURGERMEISTER, Mauren (CH)

(21) Appl. No.: 19/396,528

(22) Filed: Nov. 21, 2025

(30) Foreign Application Priority Data
Nov. 22, 2024 (DE) 10 2024 134 450.4

(51) Int. Cl. H02M 1/00; H02M 5/44; H03K 7/08

(52) U.S. Cl. CPC H02M 1/0093; H03K 7/08; H02M 5/44

(57) ABSTRACT

A method for operating a frequency converter includes the steps of: generating phase voltages with a predetermined amplitude and a predetermined frequency from an intermediate circuit voltage by pulse width modulation, wherein the phase voltages are output between associated phase connections of the frequency converter. In a first operating mode of the frequency converter, the method includes the steps of: measuring voltages between the phase connections and a reference potential; calculating the phase voltages from the measured voltages by subtraction; and regulating the phase voltages to the predetermined amplitude on the basis of the calculated phase voltages.

### CROSS REFERENCE TO RELATED APPLICATION

This application claims priority under 35 U.S.C. § 119 from German Patent Application No. 10 2024 134 450.4, filed Nov. 22, 2024, the entire disclosure of which is herein expressly incorporated by reference.

### BACKGROUND AND SUMMARY

The invention is based on the object of providing a method for operating a frequency converter and a frequency converter, which allow an output voltage to be adjusted as accurately as possible, in particular when using what are known as slim intermediate circuits and low rotating field frequencies.

The method, according to the invention, for operating a frequency converter includes the following steps.

Conventionally, phase voltages are generated with a predetermined amplitude and a predetermined frequency from an intermediate circuit voltage by means of pulse width modulation, wherein the phase voltages are output between associated phase connections of the frequency converter. In this respect, reference should also be made to the relevant technical literature.

During a first operating mode of the frequency converter, the following steps are performed: measuring voltages between the phase connections and a reference potential, in particular in the form of a negative intermediate circuit potential; calculating the phase voltages or phase-phase voltages from the measured voltages by means of subtraction; and regulating the phase voltages to the predetermined amplitude on the basis of the calculated phase voltages.

In one embodiment, measuring the voltages between the phase connections and the reference potential includes sampling the voltages and low-pass filtering the sampled voltages, wherein the cut-off frequency of the low-pass filtering is less than the fundamental frequency of the pulse width modulation, in particular is less than half the fundamental frequency of the pulse width modulation.

In one embodiment, the first operating mode is (only) activated as soon as the predetermined frequency of the phase voltages is less than or equal to a threshold frequency.

In one embodiment, a second operating mode is activated as soon as the predetermined frequency of the phase voltages is greater than the threshold frequency, wherein a fundamental frequency of the pulse width modulation is higher during the second operating mode than during the first operating mode.

In one embodiment, the phase voltages are not regulated to the predetermined amplitude during the second operating mode. Instead, a duty cycle of the pulse width modulation is adjusted on the basis of a level of the intermediate circuit voltage and on the basis of the predetermined amplitude, that is to say the amplitude is merely set, not regulated.

In one embodiment, the reference potential is a negative intermediate circuit potential.

In one embodiment, the phase voltages are regulated by means of an I controller, wherein “I” stands for integral.

In one embodiment, the manipulated variable for the regulation or control of the phase voltages is a duty cycle of the pulse width modulation.

The frequency converter according to the invention is designed to carry out the method according to the invention. The frequency converter has means for generating phase voltages with a predetermined amplitude and a predetermined frequency from an intermediate circuit voltage by means of pulse width modulation, wherein the phase voltages are output between associated phase connections of the frequency converter. The frequency converter furthermore has a measuring apparatus for measuring voltages between the phase connections and a reference potential. The frequency converter furthermore has a control unit for calculating the phase voltages from the measured voltages by means of subtraction, and regulating the phase voltages to the predetermined amplitude on the basis of the calculated phase voltages.

In one embodiment, the frequency converter has an intermediate circuit capacitor formed from one or more film capacitors.

Other objects, advantages and novel features of the present invention will become apparent from the following detailed description of one or more preferred embodiments when considered in conjunction with the accompanying drawings.

### BRIEF DESCRIPTION OF THE DRAWINGS

FIG. 1 is a schematic block diagram of a frequency converter according to an embodiment of the invention; and

FIG. 2 is a circuit diagram of a controller and a measuring apparatus of the frequency converter shown in FIG. 1.

### DETAILED DESCRIPTION OF THE DRAWINGS

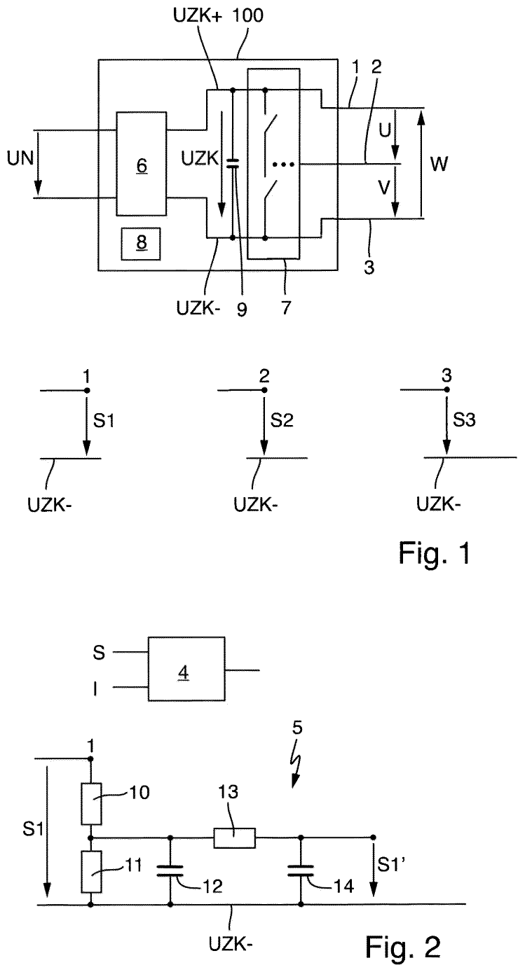

FIG. 1 shows a schematic block diagram of a frequency converter 100. The frequency converter 100 has conventional elements 6 and 7 for generating phase voltages U, V and W with a predetermined amplitude and a predetermined frequency from an intermediate circuit voltage UZK by way of pulse width modulation. In the present case, the element 6 is a rectifier for generating the intermediate circuit voltage UZK from a mains input voltage UN. In the present case, the element 7 is a conventional inverter. In this respect, reference should also be made to the relevant technical literature.

The phase voltages U, V and W are output between associated phase connections 1, 2 and 3 of the frequency converter 100.

The frequency converter 100 further has a measuring apparatus 5, see also FIG. 2, for measuring voltages S1, S2 and S3 between the phase connections 1, 2 and 3 and a reference potential or negative intermediate circuit potential UZK-. The intermediate circuit voltage UZK corresponds to the potential difference between a positive intermediate circuit potential UZK+and the negative intermediate circuit potential UZK-.

The measuring apparatus 5 has a low-pass filter, the cut-off frequency of which is less than the fundamental frequency of the pulse width modulation, in particular is less than half the fundamental frequency of the pulse width modulation. The sampled voltage, in the present case the voltage S1 as an example, is applied to an input of the measuring apparatus 5. The low-pass filtered voltage S1′ is present at the output of the low-pass filter. In the circuit shown, the measuring apparatus 5 has a voltage divider comprising resistors 10 and 11 and a downstream Pi filter comprising capacitors 12 and 14 and a resistor 13.

The frequency converter 100 further has a control unit 8, which is used, in a first operating mode, to calculate the phase voltages U, V and W from the measured voltages S1, S2 and S3 or filtered voltages S1′, S2′ and S3′ by way of subtraction. The control unit 8 is also used to regulate the phase voltages U, V and W to the predetermined amplitude on the basis of the calculated phase voltages U, V and W.

The phase voltage U corresponds, for example, to S1-S2, the phase voltage V corresponds, for example, to S2-S3, and the phase voltage W corresponds, for example, to S3 S1.

The frequency converter 100 further has an intermediate circuit capacitor 9, which is composed of one or more film capacitors.

The first operating mode is activated as soon as the predetermined frequency of the phase voltages U, V and W is less than or equal to a threshold frequency, for example 10 Hz. Accordingly, a second operating mode is activated as soon as the predetermined frequency of the phase voltages U, V and W is greater than the threshold frequency. A fundamental frequency of the pulse width modulation is higher during the second operating mode than during the first operating mode. The fundamental frequency during the second operating mode may be 8 kHz or 16 kHz, for example, and the fundamental frequency of the pulse width modulation during the first operating mode may be 2 kHz, for example.

During the second operating mode, the phase voltages U, V and W are not regulated, but set or controlled by adjusting a duty cycle of the pulse width modulation on the basis of a level of the intermediate circuit voltage UZK and on the basis of the predetermined amplitude.

The phase voltages U, V and W are regulated by an I controller 4, see FIG. 2, which may be part of the control unit 8. The variable S designates the target value for the regulation or the predetermined amplitude, for example, and the variable I designates the actual value for the regulation, for example.

The manipulated variable for the regulation of the phase voltages U, V, and W is a duty cycle of the pulse width modulation.

According to the invention, in the first operating mode, output voltage errors of the voltages U, V and W are reduced by regulation, in particular in the case of frequency converters with a slim intermediate circuit and a low switching frequency.

Conventionally, the amplitude of the phase voltages U, V and W is set by adjusting a duty ratio based on the measured intermediate circuit voltage UZK, but not regulated in a closed control loop. This is sufficiently accurate in the case of frequency converters with an electrolytic capacitor intermediate circuit.

However, in the case of low switching frequencies in conjunction with a slim intermediate circuit or low intermediate circuit capacitances, very high voltage fluctuations occur in the intermediate circuit, as a result of which the amplitude of the phase voltages U, V and W may deviate considerably from the predetermined amplitude if the amplitude is adjusted on the basis of the measured intermediate circuit voltage UZK.

According to the invention, the phase voltages U, V and W and the amplitudes thereof are calculated from the differences between the three voltages S1, S2 and S3. If the calculated amplitude of the phase voltages U, V and W deviates from the predetermined amplitude, this is compensated for by means of the I controller 4.

Since the phase voltages U, V and W may only be a few volts at low speeds, but the measurement is formed from the differences between the high voltages S1, S2 and S3, even a small measurement tolerance leads to a distortion of the measured U, V and W. Therefore, the cut-off frequency for the voltage regulation is designed such that it is below the rotating field frequency (approximately 1 Hz) and only compensates for an I component.

As a result of using the invention, the motor torque does not collapse in the case of low PWM frequencies, a slim intermediate circuit and low rotating field frequencies, but rather is kept independent of the PWM frequency on account of the regulation. In other words, the phase voltages are balanced in U/f mode (asynchronous motor).

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A method for operating a frequency converter, the method comprising the steps of:
generating phase voltages with a predetermined amplitude and a predetermined frequency from an intermediate circuit voltage by pulse width modulation, wherein the phase voltages are output between associated phase connections of the frequency converter,
wherein,
in a first operating mode of the frequency converter, the method further comprises the steps of:
measuring voltages between the phase connections and a reference potential;
calculating the phase voltages from the measured voltages by subtraction; and
regulating the phase voltages to the predetermined amplitude based on the calculated phase voltages.

2. The method for operating a frequency converter according to claim 1, wherein
measuring the voltages comprises sampling the voltages and low-pass filtering the sampled voltages,
wherein a cut-off frequency of the low-pass filtering is less than a fundamental frequency of the pulse width modulation.

3. The method for operating a frequency converter according to claim 2, wherein
the cut-off frequency of the low-pass filtering is less than half the fundamental frequency of the pulse width modulation.

4. The method for operating a frequency converter according to claim 1, wherein
the first operating mode is activated as soon as the predetermined frequency of the phase voltages is less than or equal to a threshold frequency.

5. The method for operating a frequency converter according to claim 4, wherein
a second operating mode is activated as soon as the predetermined frequency of the phase voltages is greater than the threshold frequency,
wherein the fundamental frequency of the pulse width modulation is higher during the second operating mode than during the first operating mode.

6. The method for operating a frequency converter according to claim 5, wherein
the phase voltages are not regulated to the predetermined amplitude during the second operating mode,
wherein a duty cycle of the pulse width modulation is adjusted based on a level of the intermediate circuit voltage and based on the predetermined amplitude.

7. The method for operating a frequency converter according to claim 1, wherein
the reference potential is a negative intermediate circuit potential.

8. The method for operating a frequency converter according to claim 1, wherein
the phase voltages are regulated by an I controller.

9. The method for operating a frequency converter according to claim 1, wherein
a manipulated variable for the regulation of the phase voltages is a duty cycle of the pulse width modulation.

10. A frequency converter, comprising:
means for generating phase voltages with a predetermined amplitude and a predetermined frequency from an intermediate circuit voltage via pulse width modulation, wherein the phase voltages are output between associated phase connections of the frequency converter;
a measuring apparatus for measuring voltages between the phase connections and a reference potential; and
a control unit for calculating the phase voltages from the measured voltages by subtraction, and regulating the phase voltages to the predetermined amplitude based on the calculated phase voltages.

11. The frequency converter according to claim 10, further comprising:
an intermediate circuit capacitor formed from one or more film capacitors.
